(19) United States
(12) Patent Application Publication
(10) Pub. No.: US 2012/0260846 A1
(43) Pub. Date: Oct. 18, 2012

(54) METHOD FOR FORMING BULK CRYSTALS, IN PARTICULAR MONOCRYSTALS OF FLUORIDES DOPED WITH RARE-EARTH IONS

(75) Inventors: Daniela PARISI, Cascina(Pisa) (IT); Stefano Veronesi, Pisa (IT); Mauro Tonelli, Pisa (IT)

(73) Assignee: Consiglio Nazionale Delle Ricerche, Roma (IT)

(21) Appl. No.: 13/446,424

(22) Filed: Apr. 13, 2012

(30) Foreign Application Priority Data
Apr. 14, 2011 (IT) TO2011A000335

(51) Int. Cl. C30B 15/20

(52) U.S. Cl. 117/19; 117/13; 117/202

(57) ABSTRACT

A method for forming a bulk crystal from precursors in the molten state, of solidification and growth around a seed of a material having a defined crystalline structure, includes subjecting the crystalline solid phase obtained at the end of the growth to a first controlled cooling step performed at a first higher cooling rate until a predetermined threshold temperature is reached, and to a subsequent controlled cooling step from the threshold temperature, performed at a second cooling rate lower than the first cooling rate.

This application claims benefit of Serial No. TO2011A000335, filed 14 Apr. 2011 in Italy and which application is incorporated herein by reference. To the extent appropriate, a claim of priority is made to the above disclosed application.

### FIELD OF THE INVENTION

The present invention relates to methods for producing crystalline materials, and more specifically to a method for forming a bulk crystal and to a system for forming a bulk crystal.

The invention is applicable in particular, but not exclusively, to the production of bulk monocrystals and polycrystals of fluorides doped with rare earths.

### BACKGROUND OF THE INVENTION

In the photonic industry the manufacture of latest-generation, compact, projector devices requires the use of three light-emission sources, i.e. in the red, green and blue ranges, with small dimensions of about 1 cm³ so as to be able to be incorporated in compact and sufficiently powerful devices, typically of between 60 mW and 250 mW depending on the required application. At present, sources emitting light in the red and blue ranges which satisfy the abovementioned requirements are known. On the other hand, the currently available sources which emit light at the green wavelength are still too bulky and costly or are not sufficiently powerful. Moreover, in order to maximize the emission at the wavelength concerned it is desirable that all the sources should emit in an isotropic manner.

Fluoride crystals are considered to be innovative materials in photonics and are of great importance from a technological point of view because, by activating them using trivalent rare-earth ions, it is possible to obtain solid-state continuous and pulsed laser sources emitting in a wide spectral range of wavelengths, from ultraviolet (UV) to middle infrared (MIR), with power levels of up to several hundreds of Watts. The fluorides may be grown in the form of bulk monocrystals (boules) and are suitable for numerous applications in the areas of telecommunications, latest-generation displays, imaging and the manufacturing of white-light sources. The use of crystals of KY₃F₁₀ doped with praseodymium ions Pr³⁺ for the manufacture of solid-state lasers is, for example, described in US 2010 118903. A common characteristic of fluoride crystal matrices doped with trivalent rare-earth ions is that they have a high quantum efficiency which makes them particularly attractive for the applications mentioned above. Among the various types of crystal matrices cubic matrices are of particular importance since they have an optically isotropic emission such that the fluorides with these properties are particularly low-cost and easy to use in commercial devices.

The present description describes, purely by way of a non-limiting example, the properties and growth technology of yttrium and potassium fluoride, KY₃F₁₀, the crystalline form of which has a structure which belongs to the group of fluorite, with cubic symmetry, a characteristic which is not common in fluorides. The crystal matrix of KY₃F₁₀ has a cubic symmetry with centred surfaces and is therefore optically isotropic with the same refraction index irrespective of the orientation of the crystal, such that its emission is not polarized, unlike anisotropic matrices, therefore maximizing the quantum efficiency. This characteristic, together with its optimum thermo-mechanical properties, has proved to be particularly interesting for the manufacture of low-cost optoelectronic devices which, once the crystal performance has been optimized, may be made with polycrystalline ceramic. In fact, in order to be able to produce easily the ceramic materials, which are obtained by heating in an inert atmosphere crystal powder subject to suitable isostatic pressure, the crystal matrix must be isotropic.

For the abovementioned reasons, KY₃F₁₀ is therefore an ideal candidate for the development of low-cost commercial laser sources. In order for it to be used extensively on a commercial basis the material must however be available in large homogeneous boules of optimum optical quality with a small number of defects. The samples suitable for use as laser materials must typically have a parallelepiped form with dimensions of the order of a few millimetres per side. These dimensions represent a good compromise between cornpactness and adequate absorption of the sample. In order to be able to use smaller-size samples it would be necessary in fact to use high concentrations of doping agent, with the consequent triggering of non-radiative decay processes which drastically reduce the quantum efficiency thereof and moreover may produce distortions of the crystal matrix which would therefore be of poor optical quality.

The basic cell of KY₃F₁₀ contains eight formula units and has a lattice spacing of 11.54 Å. Since it melts in a consistent manner at a temperature of about 1070° C. it is assumed that this fluoride may be easily grown in the form of large-size boules using the Czochralski method. Conventionally, in fact, with the Czochralski method it is possible to obtain monocrystals of optimum optical quality suitable for laser applications.

The standard Czochralski growing method consists in placing a seed of material to be grown in contact with the same material which is melted inside a crucible and, by means of slow upward pulling, causing gradual solidification of the melted material in the form of a mass (boule) which retains the structure and crystalline orientation of the seed to which it adheres. Once the desired dimensions of the boule have been reached, the latter is detached from the residual melt and is subject to slow cooling at room temperature suitable for minimizing the thermal stresses and their effects such as dislocations, fractures and other defects which would otherwise reduce the optical quality of the monocrystal. This procedure is common also to other methods for growing monocrystals from a molten mass such as the methods known as the Bridgman method, LHPG method, micro Pulling Down method, etc., which cover about 85% of the world production of monocrystals.

Cooling of a crystalline mass grown using the Czochralski process is obtained by controlling a decreasing-temperature ramp so as to bring the material to room temperature. In order to prevent the boule from being affected by too high thermal gradients which could result in the formation of fractures and/or dislocations in the crystal matrix, the cooling ramp is very slow and typically has a cooling rate of less than 15° C./h. Considering the working temperatures this means a cooling duration of about 3 days.

US 2008 213163 describes an improved method for growing crystals of BaLiF₃, based on the optimization of the molar ratios of the compounds of the molten starting material and on a substantially constant cooling rate of between 3 and 50° C./h.

In a disadvantageous manner it has been shown in tests that the growth of KY₃F₁₀ using the standard Czochralski method produces boules which have widespread opalescent regions, of poor optical quality, which are certainly not suitable for optoelectronic applications and which in the worst cases may cover the entire volume of the crystal. The opacification of the crystal produced by the standard growing method adversely affects the use of this material since, in the most favourable cases, it is possible to obtain only small fragments of high-quality crystal from a boule. These problems are well known and cited in the literature (see for example (1) R. Yu. Abdulsabirov, M. A. Dubinskii, B. N. Kazakov, N. I. Silkin, and Sh. I. Yagudin “New fluoride laser matrix”, Kristallografiya 32, 951-956 (1987); (2) J .P. R. Wells, A. Sugiyama, T. P. J. Han, H. G. Gallagher, “A spectroscopic comparison of samarium-doped LiYF₄ and KY₃F₁₀” J. Luminescence 87-89 1029-1031 (2000); (3) H. M. Silva, S. L. Baldochi, I. M. Ranieri “Síntese e Purificação de KY₃F₁₀” SCIENTIA PLENA 4-1 014807 (2008)) and often involve the complex task of identification of the optically “healthy” zones of the boule to be used for the spectroscopy measurements and any laser applications.

Monocrystals of KY₃F₁₀ with different concentration values of the doping ions of trivalent praseodymium (Pr³⁺) have been experimentally grown, without detecting any variation in the appearance of the monocrystals produced. It is therefore clear that the opacity defect is not dependent on the concentration of doping agent, but is an intrinsic property of the KY₃F₁₀.

In a disadvantageous manner these drawbacks are reflected in the high cost of the material since often no more than one utilizable sample can be obtained from a boule, for which all the growing cost must be borne. Moreover, the result of the process is entirely unpredictable; in fact when following the same procedure on some occasions a completely opaque boule is obtained and on other occasions a boule which is still partially utilizable is obtained.

### SUMMARY OF THE INVENTION

The object of the present invention is to provide a satisfactory solution to the abovementioned problems and more specifically to develop a method for growing crystals, in particular selected crystals of fluorides, using the Czochralski method by means of which transparent boules of high optical quality suitable for optoelectronic applications, including for example laser applications, may be obtained.

In brief, the present invention is based on modification of the current Czochralski method which envisages slow cooling of the crystalline boule formed from a melt. More specifically, the invention is based on the principle of subjecting a boule formed by means of the Czochralski method and separated from the growing melt to a first controlled cooling step with a high thermal gradient of short duration down to a threshold temperature, which is related to a possible phase transition present in the selected fluoride matrix, for example 800° C. in the specific case of KY₃F₁₀, followed by a temperature stabilization step for a predetermined period of time needed to reach a stable temperature reading by means of the thermocouple and by a second controlled cooling step with a thermal gradient lower than that of the first cooling step, but still greater than the thermal gradients which are conventionally applied in the known Czochralski method.

During tests, in the case of selected fluorides, the inventors have noted that opacification of the crystal takes place during the slow cooling processes to which the boules are subject once growth has been completed according to the known method. It was noted, in particular, that in the case of KY₃F₁₀, opacification occurs at about 800° C. This leads one to assume that the opacification effect is strictly dependent upon the cooling temperature.

According to the invention the cooling process has been modified by subjecting the boules to rapid cooling down to an opacification threshold temperature, with a cooling rate of about 100° C./min, followed by slower cooling at a rate of about 80° C./h down to room temperature. Preferably the sample is kept at the opacification threshold temperature for a predetermined period of time in order to thermo-regulate the system.

### BRIEF DESCRIPTION OF THE DRAWINGS

Further characteristic features and advantages of the invention will be explained more clearly in the following detailed description of a non-limiting example of embodiment thereof, provided with reference to the accompanying drawings in which:

FIG. 1 is a schematic illustration of an arrangement for growing crystals using the Czochralski method;

FIG. 2 is a flow diagram of the method according to the invention;

FIG. 3 is a diagram showing the variation in temperature over time during a cooling step;

FIGS. 4a and 4b are images of different samples of fluoride crystals obtained using a standard growing method and the method according to the present invention, respectively; and

FIGS. 5a and 5b are graphs showing the absorption spectra of different samples of fluoride crystals obtained using a standard growing method and the method according to the present invention, respectively.

### DETAILED DESCRIPTION OF A PREFERRED EMBODIMENT

In the remainder of the description the method for forming fluoride crystals suitable for laser applications is described and the results of laboratory tests which confirm the high quality of the samples obtained are presented.

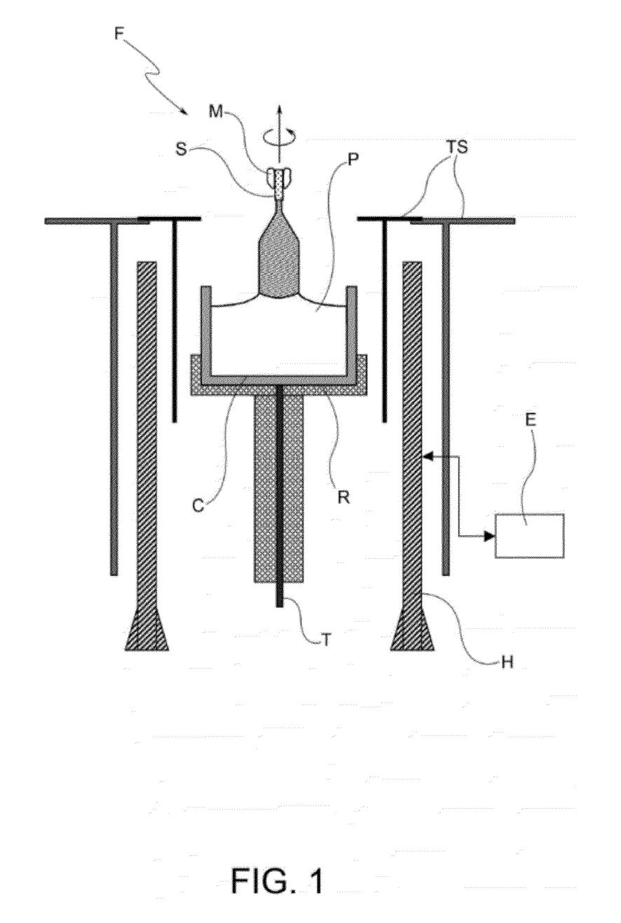

FIG. 1 shows an arrangement for growing crystals using the Czochralski method in order to form a monocrystal by means of solidification of a material which is melted around a crystal seed.

Reference C denotes a crucible, typically made of platinum or vitreous carbon, inside which a polycrystalline material P in powder form, or compounds thereof or precursor elements, is arranged, in suitable concentrations and in a suitable stoichiometric ratio for obtaining the desired crystal. The crucible is surrounded by a heating apparatus H which is designed to emit heat so as to raise the temperature inside the crucible to a value sufficient to melt the material contained inside it. The heating apparatus consists for example of a cylindrically symmetrical graphite resistance which is powered by DC voltage the current of which is controlled by a process control computer E which manages adjustment of the temperatures during the different stages of growth of the crystal mass. The crucible has a cylindrical shape, for example with a height of 50 mm and a diameter of 50 mm, and is situated in the centre of a furnace F, arranged on a support R. The latter has a hole in the centre for housing a thermocouple T, the sensitive top part of which extends into the bottom of the crucible. The thermocouple is used to monitor the temperature of the melt, which is one of the main parameters used to control the growth of the boules. Two molybdenum thermal shields TS are arranged around the crucible, their configuration providing a thermal gradient in the growth zone such as to ensure correct growing of the boule and prevent too sudden a variation in the temperature of the grown part, preventing the formation of dislocations and fractures in the crystal.

An oriented crystal seed S, consisting of the same material as that to be grown present inside the crucible in the molten state, is immersed inside the crucible, gripped by a mandrel M, in order to trigger the melt crystallization process. The seed undergoes a slow rotation (typically 5 rpm) and at the same time a slow upwards pulling force (typically 0.5-1 mm/h), subject to the control of the temperature gradient in order to take account of the heat exchanges which occur during growing in the zone surrounding the crucible, so that growing of the solid phase occurs at the solid-liquid interface. Rotation of the mandrel and its upwards movement cause extraction of the seed from the crucible and consequent pulling of a crystalline mass or boule B.

Fluorides have a melting temperature typically of between 800 and 1100° C. and the furnace is designed to operate preferably up to a temperature of 1300° C.

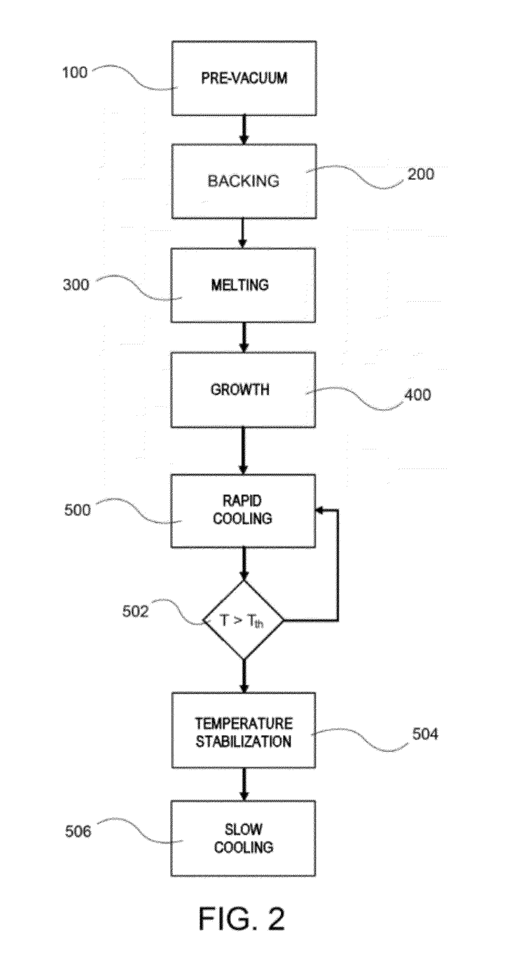

Below, and with reference to the flow diagram shown in FIG. 2, the method according to the invention is illustrated applied to the example of growing the fluoride KY₃F₁₀.

The monocrystals of fluoride are grown from fluoride powders mixed in quantities such as to respect the stoichiometry of the compound. The starting materials are introduced into the crucible C arranged at the centre of the heating apparatus H. The crucible/heater assembly is placed inside a process chamber inside which a vacuum is formed and into which an inert gas is subsequently introduced.

The growth process is divided up into five steps: pre-vacuum, backing, melting, growth and cooling.

During the pre-vacuum step, which is indicated 100 in the figure, the vacuum is formed inside the growing chamber, typically in two stages: firstly with the use of a rotary pump, which has a limit vacuum of about one hundredth of a millibar, and then by means of a turbomolecular pump, with which a residual limit pressure of 10⁻⁷ millibar can be obtained. The purpose of this preliminary operation is to eliminate moisture, oxygen and other possible gaseous contaminants which, incorporated in the crystal, could adversely affect the optical quality thereof.

During the backing step, indicated by 200 in the figure, once a predetermined residual pressure level at room temperature is reached, heating is performed while keeping the vacuum system active. This operation allows the growing chamber and the materials to be further cleaned of gases which may be adsorbed by the surfaces. The operation is managed by the computer E and the temperature of the crucible is monitored by means of the thermocouple T.

Once the backing step has been completed the vacuum generating system is stopped and inert gas, for example argon with purity 5N, is introduced into the growing chamber up to a pressure higher than atmospheric pressure, in order to prevent the damaging infiltration of ambient air into the growing chamber. After introduction of the inert gas, the crucible is heated by setting an increasing-temperature ramp such as to cause melting of the powders and obtain a homogeneous or molten liquid (step 300 in the figure).

The actual growth of the monocrystal, which is indicated by step 400 in the figure, is performed by bringing into contact with the liquid phase a seed which has the same orientation as the material which is to be grown. The seed is slowly rotated and is subjected to an upwards pulling force with parameters of the rotational speed and pulling force which are variable depending on the material being grown. The molten material accumulates around the seed and readily solidifies, assuming the orientation and the crystal structure of the original seed. Typically, with this process it is possible to grow boules with a diameter of about 20 mm and typical length of about 60 mm.

Once the desired dimensions of the boule have been reached, the latter is separated from the melt, being pulled upwards rapidly over a distance of about 5 mm and keeping it in the region of the crucible, under the direct control of the heater, and the power supply of the heater is interrupted for the time (typically a few minutes) needed for the temperature read by the thermocouple in the region of the crucible to reach an opacification threshold temperature Tₜₕ of approximately 800° C. for the KY₃F₁₀. This step involves rapid cooling of the boule, typically performed with a cooling rate (or gradient) of between 80 and 110° C./min, indicated in step 500 of the figure.

When the threshold temperature Tₜₕ is reached (verified in step 502) the heater is again energized in order to stabilize the operating temperature in the region of the threshold temperature Tₜₕ for a predetermined standby time (for example about 30 minutes) according to the properties of the furnace, this being dependent upon the mass inside and the intrinsic heat exchange coefficient of the system, as indicated in step 504.

Then a controlled cooling step 506 is started, setting a ramp for cooling down to room temperature with a cooling rate lower than the cooling rate of the previous step, for example a cooling rate (or gradient) of between 70 and 90° C./h and preferably at a rate of about 80° C./h.

The cooling rates and times depend on the dimensions and the temperature characteristics of the furnace used and may vary for different growing systems. The fundamental aspect of the growing method according to the invention, which is repeatable in any growing system, consists however in the application of a first, higher, cooling gradient in a first cooling step down to the opacification threshold temperature, and in the application of a second, different, lower cooling gradient in a second cooling step, preferably separated from the first cooling step by a short step for stabilization of the operating temperature.

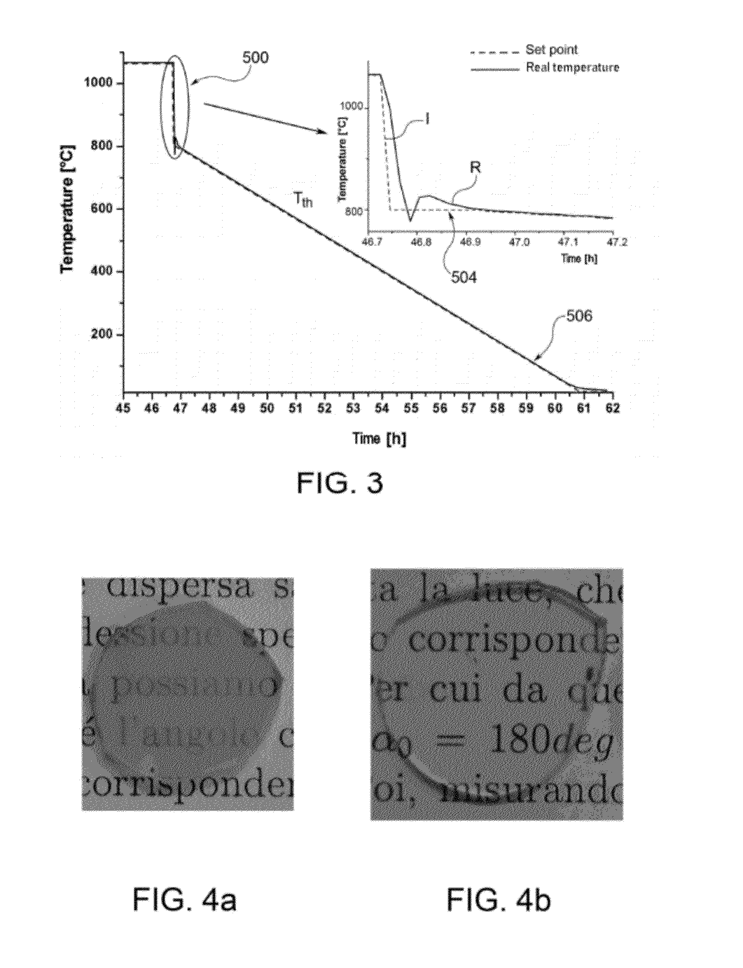

FIG. 3 shows a diagram indicating the controlled variation in temperature over time. The detail shows the progression of the real temperature R against the progression of the ideal temperature I during the temperature stabilization time interval following the rapid cooling step, before the slow cooling step.

In order to verify and evaluate quantatively the optical quality of the crystals obtained with the method according to the invention, spectroscopic measurements of the absorption values were carried out on crystal samples grown using the method described and these measurements were compared with similar measurements carried out on samples with large opalescent areas obtained according to the prior art. These measurements confirmed the significant improvement in the transparency of the crystals obtained with the method according to the present invention, which can also be understood from a visual comparison of FIGS. 4a and 4b.

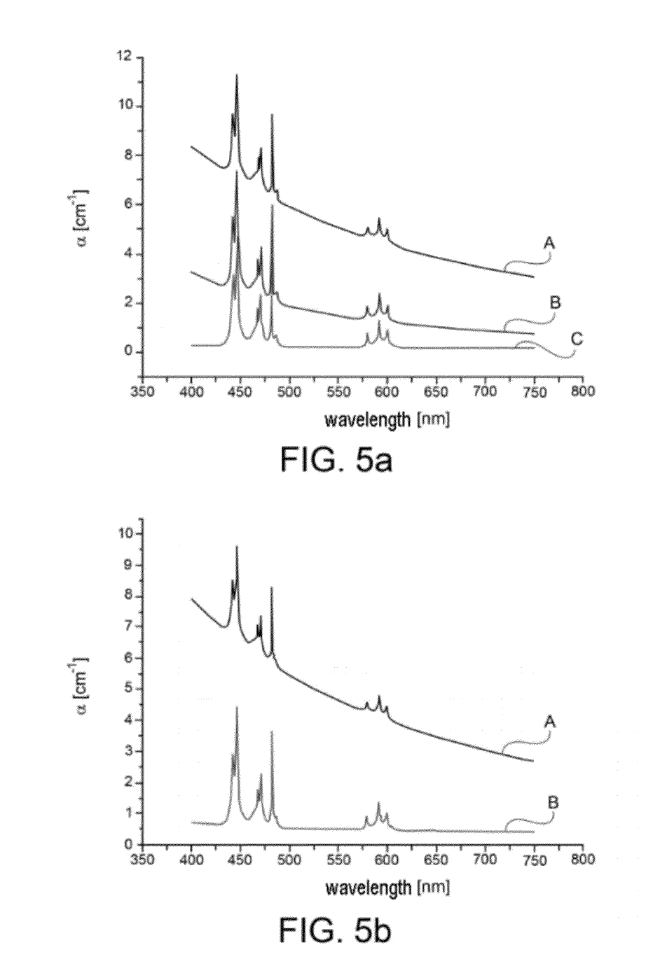

The details of the spectroscopy analyses are shown in FIGS. 5a and 5b.

FIG. 5a show the absorption spectra of three different samples of KY₃F₁₀ samples with 1.5% doping of Pr³⁺ (KY₃F₁₀:1.5 at % Pr), respectively obtained by means of a standard growing method (curve A), for example with a cooling rate of the boule of about 15° C./h, a growing method with cooling at a rate of 100° C./h (curve B), i.e. higher than the prior art, and a growing method according to the invention (curve C), namely with cooling in two stages at different rates, in any case higher than the cooling rate typical of the prior art, separated by a time interval for maintaining a predefined stabilized threshold temperature.

It is therefore clear from the data that the basic absorption, which is due to defects in the sample, is practically constant over the entire visible light range of 400 to 750 nm and less than that of the opacified samples by a factor of up to 10. Moreover, in the opacified samples the basic absorption tends to increase with a decrease in the wavelength and in the blue region of the spectrum the samples obtained with the method described have a basic absorption more than 25 times lower.

FIG. 5b shows the absorption spectra of two different samples of KY₃F₁₀ with 1% doping of Pr³⁺ (KY₃F₁₀:1 at % Pr), obtained by means of a standard growing method (curve A) and a growing method according to the invention (curve B), respectively.

From this data it can also be seen that the sample obtained with the method according to the invention (curve B) has a basic absorption which is practically constant and more than 20 times less than that of the sample obtained using a conventional growing method (curve A).

Advantageously, therefore, with the method according to the invention, it is possible to overcome the difficulties encountered with the known growing methods. This method is repeatable and allows to obtain homogeneous boules of high optical quality which are completely transparent. By applying this method it is therefore possible to produce commercial optoelectronic devices, limiting the production costs and using the appropriate doping agent depending on the intended purpose. Since the method is repeatable, the risk factor as to defects associated with growth is also significantly reduced.

In particular, the success with the growth of large-size boules of optimum optical quality by means of a crystal matrix with cubic symmetry, such as the fluoride KY₃F₁₀, opens up the way for the development of polycrystalline ceramic materials suitable for the manufacture of low-cost laser devices. This strategy has been adopted with success in the case of YAG and has resulted in the production of lasers based on polycrystalline ceramic materials with a performance which is practically identical to that of bulk monocrystals.

Moreover, since KY₃F₁₀ is not the only crystal matrix where there are difficulties with the growth of large monocrystals using the Czochralski method, the method developed according to the invention is potentially applicable also to other crystal matrices which have the same problems. The method according to the invention can be applied to other crystal matrices so as to broaden the range of materials available for the manufacture of commercial optoelectronic devices, limiting the production costs and the risk factor during growth.

It should be noted that the embodiment proposed by the present invention in the above description is intended to be a purely non-limiting example of the present invention. A person skilled in the art may easily implement the present invention using different growing arrangements and different materials without, however, departing from the principles illustrated here and without departing from the scope of protection of the invention defined by the accompanying claims.

What is claimed is:

1. Method for forming a bulk crystal from precursors in the molten state, by solidification and growth around a seed of a material having a defined crystalline structure, comprising:
subjecting a crystalline solid phase obtained at the end of the growth is subject to a first controlled cooling step performed at a first higher cooling rate until a predetermined threshold temperature is reached, and
subjecting the crystalline solid phase to a subsequent controlled cooling step from the threshold temperature, performed at a second cooling rate lower than the first cooling rate.

2. Method according to claim 1, comprising maintaining the crystalline solid phase at the threshold temperature reached at the end of the first cooling step for a predetermined time interval.

3. Method according to claim 1, wherein the bulk crystal is a fluoride.

4. Method according to claim 3, wherein the bulk crystal is a fluoride doped with rare-earth ions.

5. Method according to claim 4, wherein the bulk crystal is KY₃F₁₀:Pr³⁺.

6. System for forming a bulk crystal from precursors in the molten state, by means of solidification and growth around a seed of a material having a predefined crystalline structure, including:
a melting crucible adapted to receive the precursors in the molten state, in a stoichiometric ratio corresponding to relative ratios of the elements constituting the crystal material;
heating means associated with the melting crucible, adapted to emit heat to raise the temperature within the crucible to at least a value for melting the precursors;
means for retaining and moving a crystal seed, adapted to immerse the seed in the material in the molten state so as to trigger a process of crystallization of the molten material about the seed and extract a crystalline solid phase grown on the seed;
thermal shield means adapted to ensure a minimum thermal gradient between the crucible region receiving the precursors in the molten state and the crucible region receiving the grown crystalline solid phase;
means for detecting the temperature in at least one of the crucible region receiving the precursors in the molten state and the crucible region receiving the grown crystalline solid phase;
electronic temperature control means coupled to said heating means and arranged for operating the adjustment of the temperature during formation of the bulk crystal;
wherein the temperature control means are arranged for adjusting the cooling of the crystalline solid phase obtained at the end of the growth by implementing a method according to claim 1.
